(19) United States
(12) Patent Application Publication
(10) Pub. No.: US 2011/0121316 A1
(43) Pub. Date: May 26, 2011

(54) SILICON CARBIDE SEMICONDUCTOR DEVICE

(75) Inventor: Shinsuke Harada, Tsukuba-shi (JP)

(73) Assignee: NATIONAL INSTITUTE OF ADVANCED INDUSTRIAL SCIENCE AND TECHNOLOGY, Chiyoda-ku (JP)

(21) Appl. No.: 12/926,166

(22) Filed: Oct. 29, 2010

(30) Foreign Application Priority Data
Aug. 20, 2009 (JP) 2009-190576

(51) Int. Cl. H01L 29/161

(52) U.S. Cl. 257/77; 257/E29.084

(57) ABSTRACT

The area of each body region is minimized, and the gate oxide films at the bottoms of the trenches are more effectively protected by depletion layers extending from the body regions.

According to the present invention, an n⁻-type drift layer and a p-type base region are stacked on an n⁺-type silicon carbide substrate, and an n⁺-type source region is formed in a predetermined region of a surface portion in the base region. A gate trench is formed in a trench groove that reaches the drift layer. A p-type body region is formed at a deeper location than the gate trench. The p-type body region is adjacent to the gate trench but is not in contact with the gate trench. When viewed from above, the gate trench having a hexagonal shape surrounds the p-type body region. The side faces of the gate trench are formed only by {11-20} planes of silicon carbide.

### BACKGROUND OF THE INVENTION

1. Field of the Invention

The present invention relates to a silicon carbide semiconductor device that has a power-converting semiconductor switching device with a lower ON resistance and a higher withstand voltage with the use of a silicon carbide substrate.

2. Description of the Related Art

As a power-converting semiconductor switching device using a silicon carbide substrate, a trench MOSFET is an effective structure to lower ON-resistance, having smaller unit cell structures and a higher current density than a planar MOSFET. However, since the breakdown field of silicon carbide is high, a high electric field is applied to each gate insulating film at the bottoms of the trenches in a blocking state, and a sufficiently high withstand voltage cannot be achieved in the trench MOSFET.

FIG. 5 illustrates the structure of an n-channel vertical insulating-gate field-effect transistor (a vertical power MOSFET) disclosed in Japanese Patent Application Laid-Open No. 10-229190 (hereinafter referred to as Patent Document 1). An n⁺-type silicon carbide substrate as a low-resistance semiconductor layer is formed with the use of a hexagonal silicon carbide (Sic). An n⁻-type drift layer 2 as a high-resistance semiconductor layer and p-type base regions 13 are stacked in this order on the n⁺-type silicon carbide substrate, to form a semiconductor substrate. The plane orientation of the upper face of the semiconductor substrate is substantially a (0001−) carbon plane. In predetermined regions of the surface portions in the p-type base regions 13, n⁺-type source regions 4 are formed as semiconductor regions. Further, low-resistance p-type silicon carbide regions 41 are formed in predetermined regions of the surface portions in the p-type base regions 13.

Gate trenches 14 are formed in predetermined regions of the n⁺-type source regions 4, and the gate trenches 14 reach the n⁻-type drift layer 2, penetrating through the n⁺-type source regions 4 and the p-type base regions 3. The gate trenches 14 each have side faces perpendicular to the surface of the semiconductor substrate, and have a bottom face parallel to the surface of the semiconductor substrate. The side faces of the gate trenches 14 substantially extend in the [11-00] direction. Further, the planar shape formed by the side faces of each gate trench 14 is a hexagonal shape having the respective internal angles substantially equal to one another (approximately 120 degrees). A gate insulating film 141 is further formed on the side faces and bottom face inside each gate trench 14, and the gate trenches 14 covered with the gate insulating film 141 are filled with a gate electrode layer 142. The upper face of the gate electrode layer 142 is covered with an insulating film 15. A source electrode layer 16 is formed on the surfaces of the n⁺-type source regions 4 and the surfaces of the low-resistance p-type silicon carbide regions 41. A drain electrode layer 17 is formed under the back face of the n⁺-type silicon carbide substrate.

In the vertical power MOSFET illustrated in FIG. 5, the side faces of the gate trenches 14 of the trench MOSFET are parallel to the [11-00] direction. In other words, the side faces form hexagonal shapes having the plane orientation of (11-20), and only the planes with high channel mobility are used. Accordingly, the ON resistance is lowered. When the trench MOSFET is in an ON state in which a positive voltage is applied to the gate electrode such as the gate electrode layer 142, an inversion layer is formed in each p-type base region 13, extending along the side faces of each gate trench 14. In this manner, a current path is formed.

As the inversion layer is formed, a current flows from the drain electrode layer 17 to the n⁺-type source regions 4 and the source electrode 16 through the n⁺-type silicon carbide semiconductor, the n⁻-type drift layer 2, and the p-type base regions 13. This “forward blocking mode” of the trench MOSFET is activated when the gate-source voltage becomes lower than the threshold voltage of the MOSFET. In the forward blocking mode, an inversion layer is not formed in the channel, and an increased drain-source voltage is supported by the whole structure of the MOSFET. The gate trenches 14 extend to n⁻-type drift layer 2 through the junction portions between the p-type base regions 13 and the n⁻-type drift layer 2. Therefore, a high electric field might be formed at the corner portions of the gate trenches 14. This is not desirable, since the forward blocking voltage in this device design is lowered.

To solve this problem, Japanese Patent Application National Publication No. 2000-509559 (hereinafter referred to as Patent Document 2) discloses a trench MOSFET having p-type regions at deeper locations than gate trenches. FIG. 6 illustrates an example structure of the trench MOSFET disclosed in Patent Document 2. As shown in FIG. 6, each unit cell of the MOSFET has an n-type drift layer 18, p-type base regions 3, and n⁺-type silicon carbide regions 20 formed on an n⁺-type silicon carbide substrate. This unit cell has a gate trench 14 that extends downward into the n-type drift layer 18 through the n⁺-type silicon carbide regions 20 and the p-type base regions 3. An insulating film 141 is formed in contact with the sidewalls and bottom portion of the gate trench 14, and the insulating film 141 extends onto the upper faces of the neighboring n⁺-type silicon carbide regions 20. The gate trench 14 is made sufficiently deep, so that the upper face of the insulating film 141 formed on the bottom portion of the gate trench 14 is located deeper than the interfaces between the p-type base regions 3 and the n-type drift layer 18.

A source trench 24 is also formed in this unit cell. This source trench 24 is adjacent to the gate trench 14, and extends downward into the n-type drift layer 18 through the n⁺-type silicon carbide regions 20 and the p-type base regions 3. The source trench 24 is formed sufficiently deep, so that a p-type region 19 (a p⁺-type silicon carbide region) formed in the n-type drift layer 18 is located adjacent to a lower corner portion of the gate trench 14. As a result, an electric field concentration can be prevented when the transistor is operating in a forward blocking mode. This p⁺-type silicon carbide region 19 has a higher carrier density than the p-type base regions 3. As shown in FIG. 6, the p⁺-type silicon carbide region 19 extends deeper than the bottom portion of the gate trench 14. Also, a drain contact is formed under the lower face of the silicon carbide substrate, a source contact is formed on the upper faces of n⁺-type silicon carbide regions 20, and a gate contact is formed in contact with the insulating film 141 in the gate trench 14.

As described above, in the MOSFET illustrated in. FIG. 6, p-type regions are adjacent to the gate trench but are not in contact with the gate trench, and are formed at deeper locations than the gate trench. With this structure, a depletion layer extends from the p⁺-type silicon carbide region to the bottom of the gate trench in a blocking state, and protects the portion of the gate insulating film near the extending portion of the depletion layer from a high electric field. The above structure is also effective in restraining a decrease in withstand voltage of the p-type base regions due to a punch-through phenomenon between the source and the drain.

As described above, the p-type region 19 of the MOSFET illustrated in FIG. 6 has the function to restrain the gate insulating film from having a breakdown and improve the withstand voltage between the source and the drain. However, in a device having a current flowing vertically in the substrate, the p-type region 19 is a dead space, and causes a decrease in current density. Therefore, the area of the p-type region 19 when the device is viewed from above should preferably be minimized.

A trench MOSFET has smaller unit cell structures and has a higher current density than a planar MOSFET. Therefore, a trench MOSFET is an effective structure to lower ON resistance. However, the breakdown field of silicon carbide is high. As a result, a high electric field is applied to the gate insulating film at the bottom of each trench in a blocking state, and a sufficiently high withstand voltage cannot be achieved in a trench MOSFET.

### SUMMARY OF THE INVENTION

### Problems to be Solved by the Invention

It is therefore an object of the present invention to eliminate the above disadvantages. More specifically, the object of the present invention is to minimize the areas of body regions by designing the body regions that are adjacent to gate trenches but are not in contact with the gate trenches, and designing each gate trench surrounding each corresponding body region, and to efficiently protect the gate insulating film at the bottom of each trench by virtue of depletion layers extending from the body regions.

### Means to Solve the Problems

According to the present invention, the side faces of each gate trench are (11-20) planes with high channel mobility. In a 4H or 6H silicon carbide having a hexagonal crystalline structure, there are six symmetrical planes equivalent to {11-20} planes. Therefore, each gate trench has a hexagonal shape formed by {11-20} planes, so as to lower ON resistance.

A silicon carbide trench MOSFET of the present invention has a structure in which a drift layer of a first conductivity type and a base region of a second conductivity type are stacked on a silicon carbide substrate, a source region of the first conductivity type is formed in a predetermined region of a surface portion in the base region, and a gate trench is formed by a trench groove that reaches the drift layer. In this silicon carbide trench MOSFET of the present invention, a body region of the second conductivity type is formed at a deeper location than the gate trench, and the body region is adjacent to the gate trench but is not in contact with the gate trench. When viewed from above, the gate trench having a hexagonal shape surrounds the body region of the second conductivity type. Further, the silicon carbide trench MOSFET of the present invention is characterized in that the side faces of the gate trench are formed only by {11-20} planes of silicon carbide.

The silicon carbide substrate is preferably of an n⁺-type, the drift layer is preferably of an n⁻-type, the base region is preferably of a p-type, the source region is preferably of the n⁺-type, and the body region is preferably of the p-type.

The body region is preferably formed by a p-type region formed at the bottom of a trench groove independent of the gate trench.

Preferably, a gate insulator film is formed on the side faces and the bottom face of the gate trench, and a gate electrode is formed to fill the gate trench.

### EFFECTS OF THE INVENTION

According to the present invention, the area of the body regions is minimized. Accordingly, the dead space in an ON state is reduced. Also, the trench faces are formed by {11-20} planes having high channel mobility.

Accordingly, the withstand voltage in the structure of the MOSFET according to the present invention becomes higher than those in conventional cases, and the ON resistance can be lowered.

### BRIEF DESCRIPTION OF THE DRAWINGS

FIG. 1 illustrates the structure of a silicon carbide trench MOSFET of the present invention;

FIG. 2 shows the results of simulations done to compare differences in withstand voltages that are caused by differences between conventional example structures and the structure according to the present invention;

FIG. 3 shows the results of simulations done to compare differences in oxide field that are caused by differences between the conventional example structures and the structure according to the present invention;

FIG. 4 shows the results of simulations done to compare differences in current densities that are caused by differences between the conventional example structures and the structure according to the present invention;

FIG. 5 illustrates an n-channel vertical insulating-gate field-effect transistor (vertical power MOSFET) disclosed in Patent Document 1; and

FIG. 6 illustrates an example of a trench MOSFET disclosed in Patent Document 2.

### DETAILED DESCRIPTION OF THE PREFERRED EMBODIMENTS

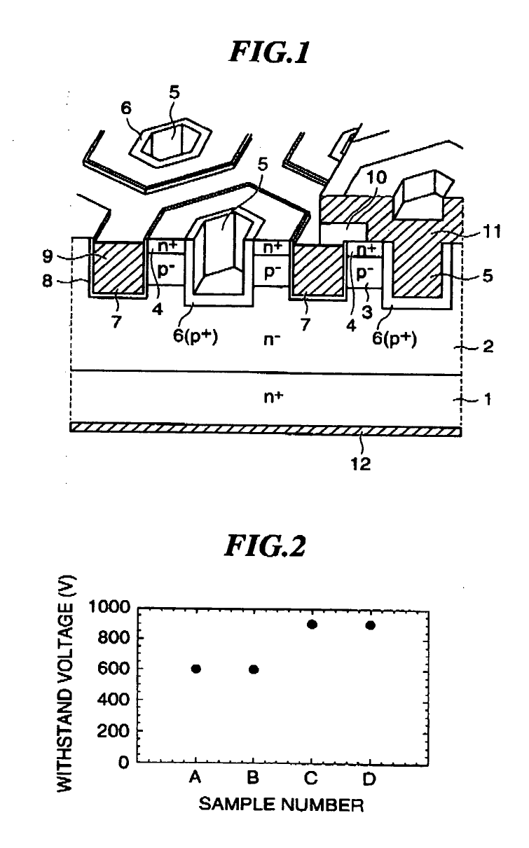

FIG. 1 shows the structure of a silicon carbide trench MOSFET of the present invention. An n⁻-type drift layer 2 having thickness of from 5 to 30 μm that is doped with nitrogen of 3×10¹⁵ to 3×10¹⁶ cm⁻³ and made of 4H-SiC is deposited on a low-resistance n⁺-type substrate 1 that is made of 4H-SiC and has a C-plane as a principal surface. The low-resistance n⁺-type substrate 1 may be a 4H-SiC substrate that has a principal surface with an orientation inclined from the (000-1) plane to one degree or less.

Further, p-type base layers 3 having thickness of from 1 to 3 μm that are doped with aluminum of 5×10¹⁶ to 2×10¹⁸ cm⁻³ and made of 4H-SiC are deposited on the type drift layer 2. The p-type base layers 3 may also be formed by an ion implantation technique.

N⁺-type source regions 4 doped with phosphorus of approximately 2×10²⁰ cm⁻³ are formed on the surfaces of the p-type base layers 3, and first trench grooves 5 that reach the n⁻-type drift layer 2 are formed in the center portions of the respective n⁺-type source regions 4. As well, when a silicon carbide trench MOSFET of the present invention is formed so that the depth of the first trench groove 5 is kept to be within the range of the thickness of the p-type base layer 3, the silicon carbide trench MOSFET also has the effects similar to the embodiment shown in FIG. 1. P-type body regions 6 doped with aluminum of approximately 5×10¹⁸ cm⁻³ are selectively formed at the bottoms of the respective first trench grooves 5.

Second trench grooves 7 that reach the n⁻-type drift layer 2 are formed adjacent to the first trench grooves 5. When viewed from above, the second trench grooves 7 hexagonally surround the first trench grooves 5. All the six sidewalls forming each one second trench groove 7 are planes equivalent to the {11-20} plane. With this arrangement, the sidewalls can be formed only by the planes with high channel mobility.

In this embodiment, the second trench grooves 7 are formed as “gate trenches”. Specifically, a gate oxide film 8 as a gate insulating film is formed on the side faces and bottom faces of the second trench grooves 7 by thermal oxidation and deposition, and a gate electrode 9 made of n-type polysilicon is formed on the gate oxide film 8 to fill the second trench grooves 7. A source electrode 11 that is in low-resistance contact with the n⁺-type source regions 4 and the p-type body regions 6 is formed above the surface of the gate electrode 9 via an interlayer insulating film 10. A drain electrode 12 is formed under the bottom face of the substrate 1.

As described above, in the silicon carbide trench MOSFET (UMOSFET) of this embodiment, the p-type body regions 6 are formed on the bottoms of the first trench grooves 5, and the second trench grooves 7 as the gate trenches are formed adjacent to the first trench grooves 5 and hexagonally surround the first trench grooves 5 when viewed from above. With this structure, in a blocking state where a high voltage is applied to the drain electrode 12, depletion layers radially extending from the p-type body regions 6 shield the gate oxide film 8 on the bottoms of the second trench grooves 7 from a high electric field. In this manner, the gate oxide film 8 is restrained from having an insulation breakdown. At the same time, the junctions between the n⁻-type drift layer 2 and the p-type base layers 3 are shielded from high electric fields, and a decrease in withstand voltage due to a punch-through phenomenon can be restrained.

Also in the above described blocking state, the depletion layers radially extend from the p-type body regions 6, and accordingly, the areas of the p-type body regions 6 can be minimized. For example, the current density in the vertical direction of the substrate 1 can be greatly increased, compared with a case where the first trench grooves 5 and the second trench grooves 7 are alternately arranged or are arranged in a striped fashion.

FIGS. 2, 3, and 4 show the results of comparisons of effects through simulations about the following conventional example structures (A)-(C) and a structure (D) of the present invention. Each n-type drift layer is doped with aluminum of 2×10¹⁶ cm⁻³ in density, and is 8 μm in thickness. Each p-type base layer is doped with aluminum of 2×10¹⁷ cm⁻³ in density, and is 2 μm in thickness. The distance between each first trench and each corresponding second trench is 1.5 μm. The structures compared are as follows:

Structure (A): a MOSFET having a unit cell structure in which the first trenches are not provided, and the second trenches are formed in a striped fashion;

Structure (B): a MOSFET having a unit cell structure in which the first trenches are not provided, and the second trenches are hexagonally formed;

Structure (C): a MOSFET having a unit cell structure in which the first trenches and the second trenches are formed in a striped fashion; and

Structure (D): a MOSFET having a unit cell structure in which the first trenches and the second trenches are hexagonally formed (the present invention).

First, when comparisons are made about the withstand voltage as shown in FIG. 2, the unit cell MOSFETs of the structures C and D have higher withstand voltages than the unit cell MOSFETs of the structures A and B. As can be seen from this fact, the depletion layers extending from the p-type layers at the bottoms of the first trenches shield the junctions between the n⁻-type drift layer and the p-type base layers from high electric fields, and restrain decreases in withstand voltage due to a punch-through phenomenon.

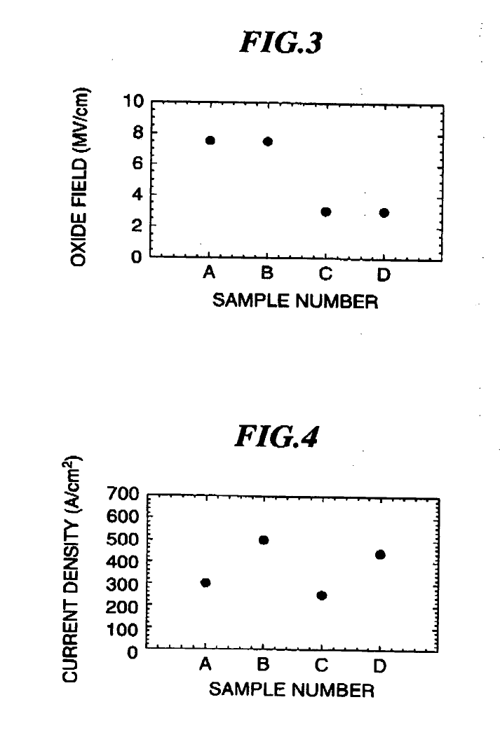

As shown in FIG. 3, when measuring withstand voltages of the MOSFETs by setting voltage applied to 600V, the electric fields induced in the gate oxide film in the unit cell MOSFETs of the structures (C) and (D) are lower than those electric fields in the structures (A) and (B). As can be seen from this fact, with regard to the respective structures (C) and (D), the depletion layers extending from the p-type layers at the bottoms of the first trenches shield the oxide film at the bottoms of the second trenches from a high electric field, and restrain the oxide film from having an insulation breakdown.

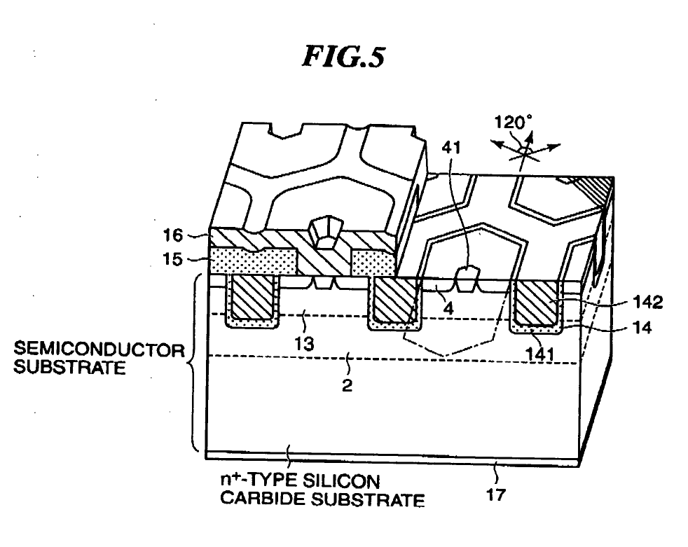

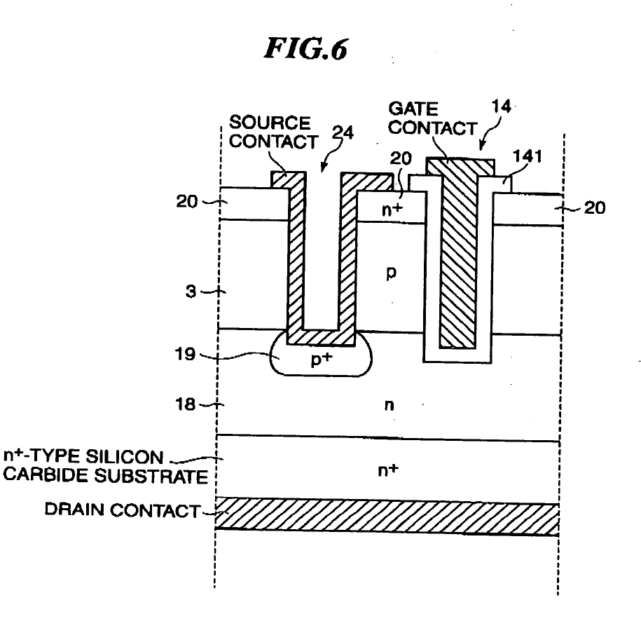

Meanwhile, as shown in FIG. 4, the unit cell MOSFETs of the structures (B) and (D) exhibit higher numerical values with respect to the ON-state current density than the unit cell MOSFETs of the structures (A) and (C). This is supposedly because the dead space is minimized by reducing the area ratio of the first trenches in the hexagonal cell structures to allow the current to flow vertically in the substrate. The current densities of the unit cell MOSFETs of the structures (C) and (D) having the first trenches maintain substantially the same values as those of the structures (A) and (B) not having the first trenches. As can be seen from this fact, the decrease in current due to the depletion layers extending horizontally from the p-type regions at the bottoms of the first trenches is small.

The silicon carbide trench MOSFET of the present invention is used as an energy-saving semiconductor device for power converters such as the motor controllers of electric vehicles and the power controllers of photovoltaic facilities.

What is claimed is:

1. A silicon carbide trench MOSFET comprising:
a silicon carbide substrate;
a drift layer of a first conductivity type and a base region of a second conductivity type that are stacked on the substrate;
a source region of the first conductivity type that is formed in a predetermined region of a surface portion in the base region; and
a gate trench that is formed in a trench groove that reaches the drift layer;
wherein a body region of the second conductivity type is formed at a deeper location than the gate trench and adjacent to the gate trench so that said body region is not in contact with the gate trench, which hexagonally surrounds the body region of the second conductivity type when viewed from above, and
wherein side faces of the gate trench are formed only by {11-20} planes of silicon carbide.

2. The silicon carbide trench MOSFET according to claim 1, wherein the silicon carbide substrate is of an n⁺-type, the drift layer is of an n⁻-type, the base region is of a p-type, the source region is of the n⁺-type, and the body region is of the p-type.

3. The silicon carbide trench MOSFET according to claim 1, wherein the body region is formed by a p-type region formed at a bottom of a trench groove independent of the gate trench.

4. The silicon carbide trench MOSFET according to claim 1, wherein a gate oxide film is formed on side faces and a bottom face of the gate trench, and a gate electrode formed to fill the gate trench.

5. The silicon carbide trench MOSFET according to claim 1, wherein the silicon carbide substrate has a C-plane as a principal surface.

6. The silicon carbide trench MOSFET according to claim 1, wherein the silicon carbide substrate is inclined from a (000-1) plane at an angle of 1 degree or less.
